(19) United States
(12) Patent Application Publication
(10) Pub. No.: US 2026/0343719 A1
(43) Pub. Date: Oct. 29, 2026

(54) Electronic Apparatus and Method for Manufacturing Electronic Apparatus

(71) Applicant: Robert Bosch GmbH, Stuttgart (DE)

(72) Inventors: Zhenzhong Shi, Suzhou (CN); Wei Zhang, Suzhou (CN); Marcel Maier, Schwieberdingen (DE); Maximilian Russ-Mohl, Schwieberdingen (DE); Lei Fang, Suzhou (CN); Mirko Gesellmann, Schwieberdingen (DE); Zhengkai Xu, Suzhou (DE)

(21) Appl. No.: 19/639,184

(22) Filed: Apr. 4, 2026

(30) Foreign Application Priority Data
Apr. 7, 2025 (CN) 2025 1042 8231.0

(51) Int. Cl. H05K 1/02; H05K 5/06

(52) U.S. Cl. CPC H05K 1/0203; H05K 5/065

(57) ABSTRACT

An electronic apparatus and a method for manufacturing an electronic apparatus. The electronic apparatus includes (i) a housing, (ii) a heat sink at least partially disposed within the housing and having a first accommodating portion, and (iii) a circuit board on which a power semiconductor component is mounted, the circuit board being at least partially located within the first accommodating portion and arranged to establish a thermal connection between the power semiconductor component and the heat sink. The first accommodating portion is filled with a first potting material to be cured, the first potting material at least partially covering the power semiconductor component. In this way, the electronic apparatus has good heat dissipation and operating performance, can improve overall power density, and avoids complex assembly within the housing of the electronic apparatus.

This application claims priority under 35 U.S.C. § 119 to application no. CN 2025 1042 8231.0, filed on Apr. 7, 2025 in China, the disclosure of which is incorporated herein by reference in its entirety.

The present application relates to the field of electronic technology, and more specifically, to an electronic apparatus and a method for manufacturing an electronic apparatus.

### BACKGROUND

With the development of technology and the increasing complexity, integration, and intelligence of apparatus functions, numerous electronic components, such as high-power-density semiconductor components, integrated chips, and processors, are installed in electromechanical apparatuses. The electronic components are typically mounted on circuit boards, such as printed circuit boards (PCBs). During operation, some electronic components may generate excessive heat due to carrier migration, switching energy loss, and high-current conditions, which can lead to heat accumulation, increased temperature, impaired performance, and shortened component lifespan.

### SUMMARY

In view of the above, the present application provides an electronic apparatus and a method for manufacturing an electronic apparatus, which can solve or at least alleviate one or more of the above-mentioned problems and other problems existing in the prior art, or can provide an alternative technical solution to the prior art.

First, according to a first aspect of the present application, an electronic apparatus is provided, comprising:
a housing;
a heat sink at least partially disposed within the housing and having a first accommodating portion; and
a circuit board on which a power semiconductor component is mounted, the circuit board being at least partially located within the first accommodating portion and arranged to establish a thermal connection between the power semiconductor component and the heat sink; wherein the first accommodating portion is filled with a first potting material to be cured, the first potting material at least partially covering the power semiconductor component.

In the electronic apparatus according to the present application, optionally, the housing has an upwardly opening accommodating space, the circuit board is installed into the first accommodating portion from above through the opening, the electronic apparatus comprises a first circuit board, the first circuit board is arranged in the housing and has electronic components mounted thereon, the circuit board is electrically connected to the first circuit board, the first circuit board covers the circuit board, and the area of the first circuit board is larger than the area of the circuit board.

In the electronic apparatus according to the present application, optionally, the first potting material is thermally conductive, the power semiconductor component is completely immersed in the first potting material, both sides of the circuit board are thermally connected to the heat sink through the first potting material, the power semiconductor component is mounted on the circuit board by surface mount technology, and the circuit board and the first circuit board are electrically connected by selective soldering process; and/or, the circuit board is arranged vertically relative to the first circuit board, and the first circuit board is arranged horizontally within the housing; and/or, the first circuit board comprises a PCBA.

Optionally, in the electronic apparatus according to the present application, the electronic apparatus comprises a second circuit board disposed within the housing and on which an electronic component is mounted, the second circuit board being electrically connected to the first circuit board.

In the electronic apparatus according to the present application, optionally, the second circuit board is arranged parallel or perpendicular to the first circuit board, and/or an electromagnetic shielding cover is provided in the accommodating space of the housing, the electromagnetic shielding cover shielding between the second circuit board and the first circuit board, and/or the electromagnetic shielding cover shielding between the second circuit board and the circuit board.

Optionally, in the electronic apparatus according to the present application, the electronic apparatus comprises a heat-generating component, and the heat sink has a second accommodating portion arranged adjacent to the first accommodating portion, the heat-generating component being at least partially located within the second accommodating portion and electrically connected to the first circuit board, the second accommodating portion being filled with a second potting material to be cured, and the heat-generating component being at least partially covered by the cured second potting material.

In the electronic apparatus according to the present application, optionally, the heat sink has a cooling channel disposed on at least one side of the first accommodating portion and/or at least one side of the second accommodating portion, the cooling channel being filled with a heat exchange medium; and/or, the heat-generating component comprises an inductor and a transformer; and/or, the second potting material is the same as the first potting material.

Optionally, in the electronic apparatus according to the present application, the electronic apparatus further comprises a cover configured to engage with the housing to at least partially close the accommodating space of the housing; and/or
the heat sink is integrally formed with the housing, or a portion of the heat sink is fixedly connected to the inner wall of the housing; and/or
the substrate of the circuit board comprises an IMS substrate, an AMB substrate, a DBC substrate, a DBA substrate, and a PCB substrate, the electronic apparatus is a charger, the power semiconductor component comprises a power semiconductor switching component, and the first potting material comprises silicone and a mixture of silicone and a thermally conductive agent.

Second, according to a second aspect of the present application, a method for manufacturing an electronic apparatus is further provided, comprising the steps of:
providing a circuit board on which a power semiconductor component is mounted;
placing the circuit board into a housing such that the circuit board is at least partially located within a first accommodating portion of a heat sink and a thermal connection is established between the power semiconductor component and the heat sink, the heat sink being at least partially disposed within the housing, and filling the first accommodating portion with a first potting material to be cured; and
after waiting for the first potting material to cure, causing the cured first potting material to at least partially cover the power semiconductor component.

Optionally, the method for manufacturing an electronic apparatus according to the present application may further comprise the steps of:
providing a first circuit board on which an electronic component is mounted and electrically connecting it to the circuit board; then placing the first circuit board and the circuit board together into the housing through an opening in the housing, such that the first circuit board covers the circuit board, and the area of the first circuit board is larger than the area of the circuit board.

Optionally, the method for manufacturing an electronic apparatus according to the present application may further comprise the steps of:
completely immersing the power semiconductor component in the first potting material, and establishing thermal connections between both sides of the circuit board and the heat sink through the first potting material, wherein the first potting material has thermal conductivity; and/or
providing a second circuit board on which an electronic component is mounted and electrically connecting it to the first circuit board, then placing the first circuit board together with the circuit board and the second circuit board into the housing through the opening; and/or
providing a heat-generating component and electrically connecting it to the first circuit board, then placing the first circuit board together with the circuit board and the heat-generating component into the housing through the opening, wherein the heat-generating component is at least partially located within a second accommodating portion of the heat sink, the second accommodating portion being arranged adjacent to the first accommodating portion and filled with a second potting material to be cured, and waiting for the second potting material to cure and at least partially cover the heat-generating component; and/or
arranging the circuit board vertically relative to the first circuit board, and arranging the first circuit board horizontally within the housing; and/or
electrically connecting the circuit board to the first circuit board using a selective soldering process; and/or
mounting the power semiconductor component onto the circuit board using surface mount technology.

By adopting the solution of the present application, on the one hand, the area occupied by the main circuit board can be effectively saved, and more power semiconductor components, such as power semiconductor switching components, can be arranged on additional circuit boards, thereby effectively improving the overall power density; on the other hand, by first electrically connecting one or more circuit boards to the main circuit board beforehand, complex assembly within the housing of the electronic apparatus can be avoided, which helps to simplify the process, ensure quality and reduce costs. In addition, the use of potting materials securely positions the circuit boards and electronic components while promoting heat dissipation, effectively reducing or eliminating the risk of thermal damage. This electronic apparatus exhibits excellent heat dissipation and stable operation, making it widely applicable to various electromechanical apparatuses.

### BRIEF DESCRIPTION OF THE DRAWINGS

FIG. 1 is a side sectional view of an embodiment of an electronic apparatus according to the present application.

FIG. 2 illustrates the processing steps of an embodiment of a method for manufacturing an electronic apparatus according to the present application.

### DETAILED DESCRIPTION

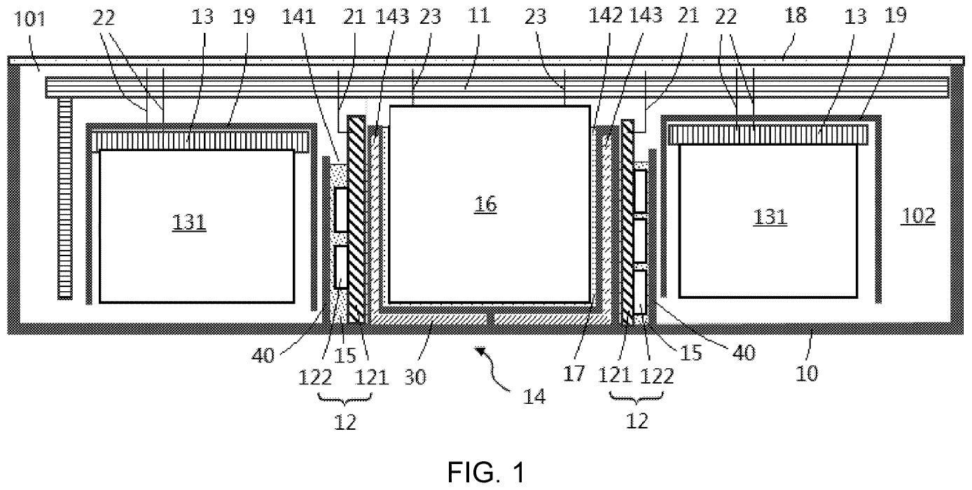

Referring to FIG. 1, the configuration of an embodiment of an electronic apparatus according to the present application is schematically shown in the accompanying figure. In this given embodiment, the electronic apparatus 100 is configured to comprise a housing 10, a first circuit board 11, a circuit board 12, a second circuit board 13, a heat sink 14, and a cover 18, etc. The electronic apparatus of the present application will now be described in detail with reference to this specific embodiment.

First, the housing 10 may be made of any one or more materials as needed, such as metals like copper, iron, aluminum, or metal alloys. The housing 10 may have a accommodating space 102 with an upward opening 101 to accommodate corresponding parts used to constitute the electronic apparatus 100. The housing 10 may be mated with the cover 18, for example, by a detachable or fixed connection, thereby allowing the accommodating space 102 to be completely or partially closed according to different application requirements.

The cover 18 may be made of any suitable material as needed, such as the same or different material as the housing 10, or suitable materials such as stainless steel or aluminum alloy, so that the electronic apparatus 100 has good electromagnetic shielding function. Although the cover 18 is schematically shown as having a flat construction in the example of FIG. 1, it should be understood that this application allows the cover 18 to be configured into any possible shape construction according to the specific application needs. For example, in one or some embodiments, the cover 18 may have structures such as curved surfaces, bulges and/or recesses.

In the electronic apparatus 100, the first circuit board 11 is electrically connected to, for example, the circuit board 12 and the second circuit board 13, and then they are arranged together through opening 101 into the accommodating space 102 of the housing 10. Then, by injecting potting material at the target location and allowing it to cure, it may achieve functions such as insulation, waterproofing and dustproofing, improving thermal conductivity, reducing heat dissipation, and/or fixing the position of components, which will be described in more detail later. The first circuit board 11 is equipped with electronic components, such as resistors, capacitors, diodes, integrated chips, etc., and the desired functional application is achieved through the configuration of the corresponding electronic components. The first circuit board 11 may typically be a PCBA (Printed Circuit Board Assembly), which means that electronic components required for the functional application may be mounted on the PCB board. The PCB board is used as a support carrier for the electronic components to connect electronic circuits. The single-layer, two-layer or more circuits set as needed on the PCB board are used to provide electronic circuits. The configured electronic components may be mounted on their respective circuit layers through processes such as bonding, sintering (such as silver sintering) or soldering (such as brazing).

As shown in FIG. 1, the circuit board 12 may comprise a substrate 121 and a power semiconductor component 122. The circuit board 12 may be electrically connected to the first circuit board 11 by any feasible process, such as selective soldering. The electrical connection between the circuit board 12 and the first circuit board 11 is schematically indicated by reference sign 21 in FIG. 1.

The substrate 121 may be, but is not limited to, an Insulated Metal Substrate (IMS) substrate, an Active Metal Brazing (AMB) substrate, a Direct Bonded Copper (DBC) substrate, a Direct Bonded Aluminum (DBA) substrate, a PCB substrate, etc. The power semiconductor component 122 may be mounted on the substrate 121 using processes such as surface mount technology. For example, the power semiconductor component 122 may be a power semiconductor switching component, such as a Metal Oxide Semiconductor Field Effect Transistor (MOSFET) and an Insulated Gate Bipolar Transistors (IGBT). One, two, or more power semiconductor components 122 may be configured on the circuit board 12 as needed; they may be the same or different component types. The power semiconductor component 122 may be completely or partially covered by immersion in a first potting material 15 to be cured (such as silicone, or a mixture of silicone and a thermally conductive agent). Specific implementations may be designed as needed.

In one or more embodiments, after the first potting material 15 has cured, the substrate 121 and the power semiconductor component 122 may be fixed in the expected position. That is, the circuit board 12 may be fixed in place. This avoids the conventional method of using mechanical parts (such as spring sheets) to directly press and fix the power semiconductor component mounted on the circuit board, which is often used in the prior art. Such methods are prone to problems such as troublesome installation and operation, space occupation, poor long-term fixation effect, affecting heat dissipation, and increasing costs. The above solution of the present application can successfully overcome the above problems.

By providing an additional circuit board 12, the area occupied by the first circuit board 11, which serves as the main circuit board, can be significantly reduced. More power semiconductor components may be arranged on the substrate 121 of the circuit board 12, thereby significantly improving the overall power density of the electronic apparatus and solving the problem of low power density in existing electronic apparatus products. In addition, unlike existing technical solutions, by first electrically connecting the circuit board 12 and the first circuit board 11, and then arranging them together inside the housing of the electronic apparatus through the opening 101, the circuit board 12 may be immersed in the first potting material 15 to be cured. After the first potting material 15 cures, it may fix the position of the circuit board 12 and thus define the position of the first circuit board 11. This avoids the assembly operation inside the housing commonly used in the industry. Therefore, it not only simplifies the process and avoids the original complex assembly operation, improving work efficiency, but also helps to improve product quality and reduce production costs. Even in special cases, such as when the first circuit board 11 has a relatively large size (e.g., the first circuit board 11 has a larger area than the circuit board 12 and is arranged inside the housing 10 covering the circuit board 12), the solution of the present application will not affect the fixed position of the circuit board 12 within the housing of the electronic apparatus. However, with existing technologies, the first circuit board 11 occupies limited space within the housing, leading to difficulties in subsequent operations, or even making operation impossible. The second circuit board 13 and the heat-generating component 16, discussed below, may also achieve these positive and significant technical effects using the above or similar methods.

When the first circuit board 11, together with the electrically connected circuit board 12, is placed into the housing 10 through the opening 101, a thermal connection is established between the power semiconductor component 122 on the circuit board 12 and the heat sink 14. This forms a heat transfer path between the heat sink 14 and the power semiconductor component 122, allowing the heat sink 14 to dissipate heat and cool the power semiconductor component 122. This helps prevent heat buildup, effectively reducing or eliminating the risk of thermal damage to components and improving system stability. Alternatively, as in this embodiment, the circuit board 12 may be arranged perpendicularly to the first circuit board 11. For example, the first circuit board 11 and the circuit board 12 may be arranged horizontally and vertically within the housing 10, respectively. This allows for flexible use of the limited space within the housing, enabling the placement of a relatively larger number of power semiconductor components 122 on the circuit board 12, thereby increasing the overall power density. In different applications, one, two or more circuit boards 12 may be arranged as needed within the housing 10 of the electronic apparatus of the present application. For example, the example in FIG. 1 exemplarily shows a configuration of two circuit boards 12, which are arranged at intervals in the accommodating space 102 and each is provided with a different number of power semiconductor components 122.

As an optional configuration, the electronic apparatus 100 also comprises one or more second circuit boards 13. As used in the example of FIG. 1, the second circuit board 13 may be arranged parallel to the first circuit board 11; of course, in one or more embodiments, one or more second circuit boards 13 may be arranged perpendicularly to the first circuit board 11. Any suitable electronic components 131 may be mounted on the second circuit board 13, which may cooperate with the first circuit board 11 and/or circuit board 12 to realize the functional applications of the electronic apparatus 100. For example, the second circuit board 13 may be used to perform various possible functions such as signal filtering, boosting, or bucking.

The second circuit board 13 may be electrically connected to the first circuit board 11, for example, through any feasible process such as selective soldering. The electrical connection between the second circuit board 13 and the first circuit board 11 is schematically shown in FIG. 1 using reference sign 22. Depending on the application requirements, the present application allows for the configuration of one, two, or more second circuit boards 13 in the electronic apparatus. Furthermore, in one or more embodiments, an electromagnetic shielding cover 19, such as an aluminum alloy shield, may be optionally configured for one or more second circuit boards 13. The electromagnetic shielding cover 19 may be configured as needed to shield between the second circuit board 13 and the first circuit board 11, and/or between the second circuit board 13 and the circuit board 12, in order to better avoid unwanted signal interference and improve the operating performance of the electronic apparatus.

The heat sink 14 is disposed in the electronic apparatus 100 to provide functions such as heat dissipation and cooling. The heat sink 14 is generally made of metal materials such as copper or aluminum to ensure good heat transfer performance. In the embodiment of FIG. 1, the heat sink 14 is integrally formed with the housing 10, for example, by stamping, casting, or machining. This helps to maintain the overall structure of the electronic apparatus and increases the heat dissipation area. In one or more embodiments, the heat sink 14 may be designed and manufactured separately, and then a portion of the heat sink 14 (such as the bottom, side, etc.) is fixedly connected to the inner wall of the housing 10, for example, by welding, plugging, screwing, or any other feasible method. Furthermore, in one or more embodiments, a portion of the heat sink 14 may extend to the outside of the housing 10.

Referring to the exemplary structure shown in FIG. 1, the heat sink 14 may be configured to have a first accommodating portion 141 and a second accommodating portion 142. For example, from the side view shown in FIG. 1, the heat sink 14 may be configured as an upward-opening U-shape to form, for example, the first accommodating portion 141 and/or the second accommodating portion 142, for housing such as the circuit board 12, the heat-generating component 16, etc. The volume, structure, arrangement, and number of these accommodating portions may be designed as needed.

For example, the first accommodating portion 141 may be defined by the sidewall of the heat sink 14, the sidewall of the vertical structure 40 inside the housing 10 (or the inner wall of the housing 10 itself), and the bottom surface formed by the housing 10 or the heat sink 14. This structural configuration facilitates the filling of the curable first potting material 15 into the first accommodating portion 141. The aforementioned vertical structure 40 may be integrally formed with the housing 10 or structurally integrated through processes such as welding. It may be used for synergistic heat dissipation and may therefore be understood as being integrated into the heat sink 14. The circuit board 12, either entirely or partially, may be placed inside the first accommodating portion 141. When the first potting material 15 to be cured is injected into the first accommodating portion 141, the first accommodating portion 141 may be filled entirely or partially by the first potting material 15 as needed. This achieves the purpose of fixing the circuit board 12 in place and at least partially covering the power semiconductor component 122 after the circuit board 12 is immersed in the first potting material 15 and cured. The second accommodating portion 142 is optionally arranged adjacent to the first accommodating portion 141. At least partially, the heat-generating component 16, which is also an optional component in the electronic apparatus 100, may be arranged within the second accommodating portion 142 so that the heat sink 14 may be used to dissipate heat and cool the heat-generating component 16. For example, the heat-generating component 16 may include, but is not limited to, inductors, transformers, such as Power Factor Correction (PFC) converters, Dual Active Bridge (DAB) converters, etc. The heat-generating component 16 and the first circuit board 11 may be electrically connected using any feasible method, such as selective soldering process. The electrical connection between the heat-generating component 16 and the first circuit board 11 is schematically indicated by reference sign 23 in FIG. 1.

When manufacturing the electronic apparatus 100, the first circuit board 11, together with the circuit board 12 electrically connected to it, the heat-generating component 16, and the second circuit board 13 (if any), may be placed into the housing 10 through the opening 101. This allows the heat-generating component 16 to be immersed in the second potting material 17 (such as silicone, or a mixture of silicone and a thermally conductive agent) that has been injected into the second accommodating portion 142 and is to be cured. Depending on the application requirements, the second accommodating portion 142 may be completely or partially filled with the second potting material 17. By way of the cured second potting material 17, the heat-generating component 16 may be completely or partially covered by the potting material.

In different applications, the second potting material 17 may be the same as or different from the first potting material 15. For example, it can be different types of silicone, or different mixtures made by mixing silicone with different thermally conductive agents (such as alumina, boron nitride, silicon nitride, etc.), or a variety of other potting materials that can be used in semiconductor electronics technology, so as to fully meet various practical needs. In actual use, the first potting material 15 and the second potting material 17 with suitable thermal conductivity may be selected as needed, for example, in the range of 0.5-3.0 W/(m·K), such as 0.5 W/(m·K), 0.6 W/(m·K), 1 W/(m·K), 1.5 W/(m·K), 2.0 W/(m·K), 2.5 W/(m·K) or 3 W/(m·K), and so on. The specific coverage thickness of the first potting material 15 and the second potting material 17 at their respective potting locations may be set as needed, for example, within the range of 0.5 mm to 3 mm, such as 0.5 mm, 0.8 mm, 1 mm, 1.5 mm, 2 mm, 2.5 mm, or 3 mm, and so on. The values listed above are for illustrative purposes only, and the present application does not impose any specific limitations.

By configuring and using the first potting material 15 and/or the second potting material 17 with thermal conductivity, heat dissipation and cooling are more effectively promoted. For example, in one or more embodiments, the power semiconductor component 122 may be completely immersed in such a first potting material 15, and both sides of the circuit board 12 may be thermally connected to the heat sink 14 through such a first potting material 15, so as to better utilize the heat sink 14 for heat dissipation and cooling, and to dissipate heat in a timely manner.

Referring again to FIG. 1, as disclosed in this embodiment, the heat sink 14 may be configured with a cooling channel 143 so that heat exchange medium 30 (such as water or other suitable liquid) filled in the cooling channel 143 may exchange heat with the power semiconductor component 122, heat-generating component 16, etc., as described above, thereby promoting timely heat dissipation, reducing the temperature of these components, and preventing heat accumulation. The cooling channels 143 may be designed in terms of structure, arrangement, and quantity according to specific requirements. For example, the cooling channels 143 may be provided on at least one side of the first accommodating portion 141 or at least one side of the second accommodating portion 142, or the cooling channels 143 may be provided on one or more sides of the first accommodating portion 141 and the second accommodating portion 142 simultaneously. The present application does not impose any limitations on this.

It should be noted that the electronic apparatus is allowed to have many possible implementation types, such as AC-DC converter, DC-DC converter, charger, rectifier, inverter, bidirectional power converter, etc., and the present application does not make any restrictions in this regard.

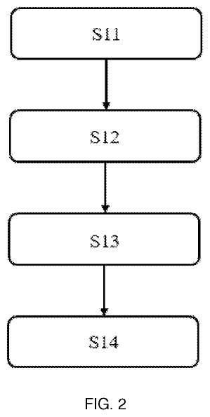

According to the present application, a method for manufacturing an electronic apparatus is also provided. For example, a specific example is given in FIG. 2. This embodiment of the method for manufacturing an electronic apparatus may comprise the following steps:

First, in step S11, a first circuit board and a circuit board on which a power semiconductor component is mounted (hereinafter referred to as “additional circuit board”) may be provided. The first circuit board and the additional circuit board have been described above; please refer to the relevant descriptions;

In step S12, the first circuit board and the additional circuit board may be electrically connected in any feasible manner. For example, the additional circuit board may be soldered to the corresponding circuit layer on the first circuit board using a selective soldering process as described above;

In step S13, both the electrically connected first circuit board and the additional circuit board may be placed into the housing of the electronic apparatus through an opening in the housing. A heat sink is provided inside the housing. During placement, the additional circuit board may be positioned at a preset location, allowing the power semiconductor component on the additional circuit board to establish a thermal connection with the heat sink. For example, the additional circuit board may be immersed in a first potting material that has been filled into the first accommodating portion of the heat sink and is to be cured, thus enabling the heat sink to dissipate heat and cool the power semiconductor component on the additional circuit board;

In step S14, after the first potting material has cured, the power semiconductor component on the additional circuit board may be partially or completely covered by the first potting material.

The configuration and use of the first circuit board, the additional circuit board, the second circuit board, the heat sink, and the first and second potting materials have been discussed in detail above. Therefore, more step features may be obtained by referring to the relevant descriptions, thereby forming more specific implementation schemes of this method for manufacturing an electronic apparatus.

For example, one or more second circuit boards may be provided and electrically connected to the first circuit board, for example, using a selective soldering process. The first circuit board, along with the additional circuit board and the second circuit board, is then placed into the housing of the electronic apparatus through an opening in the housing. For instance, the first circuit board may be arranged inside the housing, covering the additional circuit board, and it may have a larger area than the additional circuit board. Of course, in one or more embodiments of the method according to the present application, only the additional circuit board may be provided and arranged inside the housing of the electronic apparatus, for example, by immersing it in a first potting material that has been filled into a first accommodating portion of a heat sink and is to be cured. The additional circuit board is then positioned and fixed after the first potting material has cured.

For another example, one or more heat-generating components may be provided and electrically connected to a first circuit board. The first circuit board, along with an additional circuit board and the heat-generating components, is then placed into the housing of the electronic apparatus through an opening in the housing. This positions the heat-generating components in a position where they can maintain thermal connection with the heat sink. For instance, the heat-generating components may be completely or partially immersed in a second potting material that has been filled into a second accommodating portion of the heat sink and is to be cured, thereby fixing the heat-generating components in place. Alternatively, the additional circuit board may be arranged vertically relative to the first circuit board, while the first circuit board is arranged horizontally within the housing of the electronic apparatus. Furthermore, the first potting material may be filled between the additional circuit board and the heat sink after curing, or both sides of the additional circuit board may establish thermal connection with the heat sink through the first potting material, allowing the power semiconductor component to be completely immersed in the first potting material, thus better achieving one or more positive effects such as insulation, component fixation, heat dissipation, and waterproofing/dustproofing.

The electronic apparatus and the method for manufacturing an electronic apparatus according to the present application are described in detail by way of example only. These examples only serve to demonstrate the principles and implementation methods of the present application, and do not constitute a limitation on the present application. Without departing from the scope of the present application, those skilled in the art may also make various modifications and improvements. Therefore, all equivalent technical solutions shall fall within the scope of the present application and be defined by the various claims of the present application.

What is claimed is:

1. An electronic apparatus, comprising:
a housing;
a heat sink at least partially disposed within the housing and having a first accommodating portion; and
a circuit board on which a power semiconductor component is mounted, the circuit board being at least partially located within the first accommodating portion and arranged to establish a thermal connection between the power semiconductor component and the heat sink,
wherein the first accommodating portion is filled with a first potting material that at least partially covers the power semiconductor component.

2. The electronic apparatus according to claim 1, wherein the housing is provided with an accommodating space with an upward opening, the circuit board is installed into the first accommodating portion from above through the opening, the electronic apparatus comprises a first circuit board, the first circuit board is arranged in the housing and is equipped with an electronic component, the circuit board is electrically connected to the first circuit board, the first circuit board covers the circuit board, and the area of the first circuit board is larger than the area of the circuit board.

3. The electronic apparatus according to claim 2, wherein the first potting material is thermally conductive, the power semiconductor component is completely immersed in the first potting material, both sides of the circuit board are thermally connected to the heat sink through the first potting material, the power semiconductor component is mounted on the circuit board by surface mount technology, and the circuit board and the first circuit board are electrically connected by selective soldering process; and/or, the circuit board is arranged vertically relative to the first circuit board, and the first circuit board is arranged horizontally in the housing; and/or, the first circuit board comprises a PCBA.

4. The electronic apparatus according to claim 2, wherein the electronic apparatus comprises a second circuit board, the second circuit board is disposed in the housing and has an electronic component mounted thereon, and the second circuit board is electrically connected to the first circuit board.

5. The electronic apparatus according to claim 4, wherein the second circuit board is arranged parallel or perpendicular to the first circuit board, and/or an electromagnetic shielding cover is provided in the accommodating space of the housing, the electromagnetic shielding cover shielding between the second circuit board and the first circuit board, and/or the electromagnetic shielding cover shielding between the second circuit board and the circuit board.

6. The electronic apparatus according to claim 2, wherein the electronic apparatus comprises a heat-generating component, and the heat sink has a second accommodating portion arranged adjacent to the first accommodating portion, the heat-generating component being at least partially located within the second accommodating portion and electrically connected to the first circuit board, the second accommodating portion being filled with a second potting material, and the heat-generating component being at least partially covered by the cured second potting material.

7. The electronic apparatus according to claim 6, wherein the heat sink has a cooling channel disposed on at least one side of the first accommodating portion and/or at least one side of the second accommodating portion, the cooling channel being filled with a heat exchange medium; and/or, the heat-generating component comprises an inductor and a transformer; and/or, the second potting material is the same as the first potting material.

8. The electronic apparatus according to claim 1, wherein the electronic apparatus further comprises a cover configured to engage with the housing to at least partially close the accommodating space of the housing; and/or
the heat sink is integrally formed with the housing, or a portion of the heat sink is fixedly connected to the inner wall of the housing; and/or
the substrate of the circuit board comprises an IMS substrate, an AMB substrate, a DBC substrate, a DBA substrate, and a PCB substrate, the electronic apparatus is a charger, the power semiconductor component comprises a power semiconductor switching component, and the first potting material comprises silicone and a mixture of silicone and a thermally conductive agent.

9. A method for manufacturing an electronic apparatus, comprising:
providing a circuit board on which a power semiconductor component is mounted;
placing the circuit board inside a housing such that the circuit board is at least partially located within a first accommodating portion of a heat sink, and establishing a thermal connection between the power semiconductor component and the heat sink, the heat sink being at least partially disposed within the housing, the first accommodating portion being filled with a first potting material to be cured; and
after waiting for the first potting material to cure, causing the cured first potting material to at least partially cover the power semiconductor component.

10. The method according to claim 9, further comprising:
providing a first circuit board on which the electronic component is mounted and electrically connecting it to the circuit board, and then placing the first circuit board and the circuit board together into the housing through an opening provided on the housing, such that the first circuit board covers the circuit board, and the area of the first circuit board is larger than the area of the circuit board.

11. The method according to claim 10, further comprising:
immersing the power semiconductor component completely in the first potting material, and establishing thermal connections between both sides of the circuit board and the heat sink through the first potting material, wherein the first potting material is thermally conductive; and/or
providing a second circuit board on which the electronic component is mounted and electrically connecting it to the first circuit board, and then placing the first circuit board together with the circuit board and the second circuit board into the housing through the opening; and/or
providing a heat-generating component and electrically connecting it to the first circuit board, then placing the first circuit board together with the circuit board and the heat-generating component into the housing through the opening, and positioning the heat-generating component at least partially within a second accommodating portion of the heat sink, the second accommodating portion being arranged adjacent to the first accommodating portion and filled with a second potting material to be cured, and waiting for the second potting material to cure and at least partially cover the heat-generating component; and/or
arranging the circuit board vertically relative to the first circuit board, and arranging the first circuit board horizontally within the housing; and/or
electrically connecting the circuit board to the first circuit board by a selective soldering process; and/or
mounting the power semiconductor component onto the circuit board using surface mount technology.
